(19) United States
(12) Patent Application Publication
(10) Pub. No.: US 2024/0355703 A1
(43) Pub. Date: Oct. 24, 2024

(54) HEAT DISSIPATIVE SEMICONDUCTOR PACKAGE

(71) Applicant: PANJIT INTERNATIONAL INC., KAOHSIUNG CITY (TW)

(72) Inventors: CHUNG-HSIUNG HO, KAOHSIUNG CITY (TW); CHI-HSUEH LI, TAINAN CITY (TW); CHE FANG, KAOHSIUNG CITY (TW)

(21) Appl. No.: 18/334,622

(22) Filed: Jun. 14, 2023

(30) Foreign Application Priority Data
Apr. 18, 2023 (TW) 112114348

(51) Int. Cl. H01L 23/367; H01L 23/00; H01L 23/498; H01L 23/538; H01L 25/065

(52) U.S. Cl. CPC H01L 23/3675; H01L 23/49827; H01L 23/5384; H01L 23/5386; H01L 24/32; H01L 25/0652; H01L 2224/32137; H01L 2224/3223; H01L 2225/1058

(57) ABSTRACT

The present invention provides a heat dissipative semiconductor package. The semiconductor package includes a package body in a flat rectangular shape. The semiconductor package further includes a die, a conductive block, multiple metal blocks, a molding layer, and a redistribution layer. A first contact of the die is electrically connected to a first pin. A second contact of the die is electrically connected to a second pin via the redistribution layer and the conductive block. The first pin and the second pin are respectively exposed from the bottom surface of the package body to curve, extend, and cover different side surfaces of the package body. The conductive block and the metal blocks are formed by dicing a same VCB. Heat generated by the die can be effectively dissipated externally through the first pin, the second pin, and the conductive block, and thus cooling the die.

### CROSS-REFERENCE TO RELATED APPLICATION(S)

This application claims the priority benefit of TW application serial No. 112114348 filed on Apr. 18, 2023, the entirety of which is hereby incorporated by reference herein and made a part of the specification.

### BACKGROUND OF THE INVENTION

### 1. Field of the Invention

The present invention relates to a semiconductor package, more particularly a semiconductor package with great heat dissipation and great electrical conductivity.

### 2. Description of the Related Art

With reference to FIG. 11, FIG. 11 shows a cross-sectional perspective view of a conventional semiconductor package. The conventional semiconductor package, such as a dual in-line package (DIP), includes a first lead 201, a second lead 202, and a die 203. The first lead 201 is formed by a first conduction frame (lead frame), and a surface of the first lead 201 is adhered to a bottom surface of the die 203. The second lead 202 is formed by a second conduction frame (clip/jumper), and a side of the second lead 202 is electrically connected to a top surface of the die 203. A molding layer 204 made of dielectric materials covers the first lead 201, the second lead 202, and the die 203. An external portion of the first lead 201 and an external portion of the second lead 202 respectively extend outside of the molding layer 204, allowing the external portion of the first lead 201 and the external portion of the second lead 202 to be soldered to an external circuit board.

However, the conventional semiconductor package shown in FIG. 11 is not suitable for conducting large amounts of electric current. Furthermore, since both the top surface and the bottom surface of the die 203 are surrounded by great amounts of dielectric material, the die 203 fails to dissipate heat efficiently.

### SUMMARY OF THE INVENTION

To overcome the aforementioned problem, the present invention provides a heat dissipative semiconductor package. The present invention is able to increase heat dissipation of a semiconductor package by making the semiconductor package thin. The semiconductor package of the present invention is also applicable to conduct greater electric current.

The present invention provides a heat dissipative semiconductor package, and the heat dissipative semiconductor package includes a package body in a flat rectangular shape. The package body includes a top surface, a bottom surface, and four side surfaces. The semiconductor package further includes:
a die, having two opposite sides; wherein the two opposite sides respectively have a first contact and a second contact;
a conductive block, mounted a distance away from a side of the die by having a gap; wherein the conductive block has a first contact surface and a second contact surface;
multiple metal blocks, lined up around the die and without electrically connecting to the die; wherein a dicing surface of each of the metal blocks is exposed to one of the side surfaces of the package body;
a molding layer, covering the die, the conductive block, and the metal blocks, and exposing the four side surfaces of the package body;
a first redistribution layer, including a first pin and a second pin; wherein the first pin is electrically connected to the first contact of the die, and the first pin is exposed from the bottom surface of the package body to curve, extend, and cover one of the side surfaces of the package body; wherein the second pin is electrically connected to the second contact surface of the conductive block, and the second pin is exposed from the bottom surface of the package body to curve, extend, and cover another one of the side surfaces of the package body;
a second redistribution layer, electrically connected to the second contact of the die and the first contact surface of the conductive block; and
a solder mask, formed on the bottom surface and the top surface of the package body; wherein the solder mask on the bottom surface insulates the first pin and the second pin, and the solder mask on the bottom surface covers the second redistribution layer.

The semiconductor package is independent, and the semiconductor package includes a package body in a flat rectangular shape. This allows the semiconductor package to be a surface mounting package. For each of the dies in the semiconductor package, a contact on a surface of the die is electrically connected to the first pin (S1), a contact on an opposite surface of the die is electrically connected to the conductive block via the second redistribution layer, and the conductive block is further electrically connected to the second pin (S2). The first pin (S1) and the second pin (S2) are mounted on a bottom surface of the package body, and the first pin and the second pin are respectively exposed from the bottom surface of the package body to curve, extend, and cover two opposite sides of the side surfaces of the package body. The semiconductor package of the present invention is able to solder the first pin (S1) and the second pin (S2) on the bottom surface to a circuit board. The first pin (S1) and the second pin (S2) extending to the two opposite sides of side surfaces are provided for soldering, and as such, soldering quality may be easily inspected.

Since each of the dies is able to dissipate heat externally through heat conduction of the first pin, the second pin, and the conductive block, the present invention allows better heat dissipation for each of the dies. Furthermore, since the semiconductor package is more electrically conductive, the semiconductor package is suitable for conducting greater electric current.

### BRIEF DESCRIPTION OF THE DRAWINGS

FIG. 1 is a partial surface perspective view of a vertical connection board (VCB) used in a manufacturing method of the present invention.

FIG. 2 is an enlarged partial surface perspective view of the VCB used in the manufacturing method of the present invention.

FIG. 3A is a bottom three-dimensional external view of the VCB used in the manufacturing method of the present invention.

FIG. 3B is a top three-dimensional external view of the VCB used in the manufacturing method of the present invention.

FIGS. 4A to 4O are perspective views of flow charts of the manufacturing method of a semiconductor package in a first embodiment of the present invention.

FIG. 5 is a cross-sectional perspective view of the semiconductor package in the first embodiment of the present invention after completing manufacturing steps detailed in FIGS. 4A to 4O.

FIG. 6 is a cross-sectional perspective view of the semiconductor package in a second embodiment of the present invention.

FIG. 7 is a cross-sectional perspective view of the semiconductor package in a third embodiment of the present invention.

FIGS. 8A to 8O are perspective views of flow charts of the manufacturing method of the semiconductor package in the second embodiment of the present invention.

FIG. 9 is a cross-sectional perspective view of the semiconductor package of the present invention after completing manufacturing steps detailed in FIGS. 8A to 8O.

FIG. 10 is a three-dimensional external perspective view of the semiconductor package of the present invention.

FIG. 11 is a cross-sectional perspective view of a conventional semiconductor package.

### DETAILED DESCRIPTION OF THE INVENTION

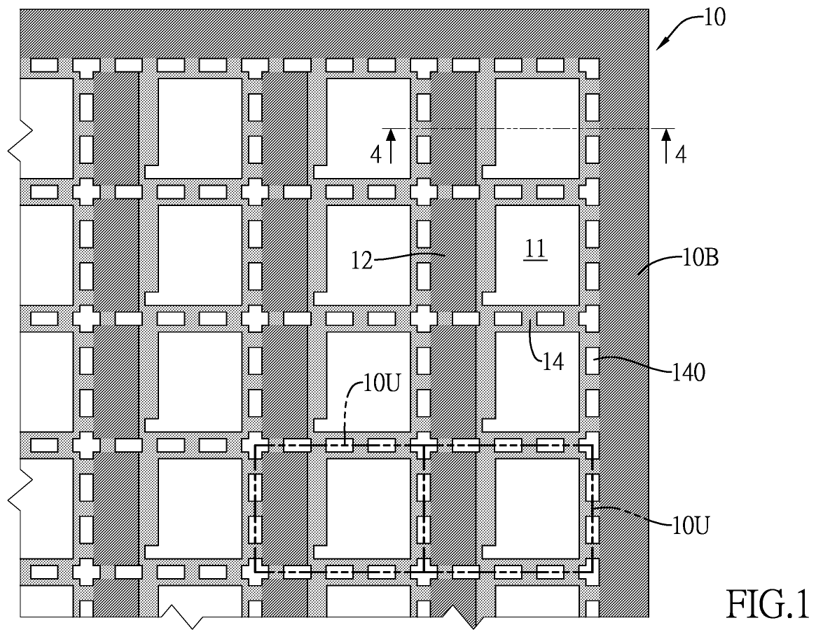

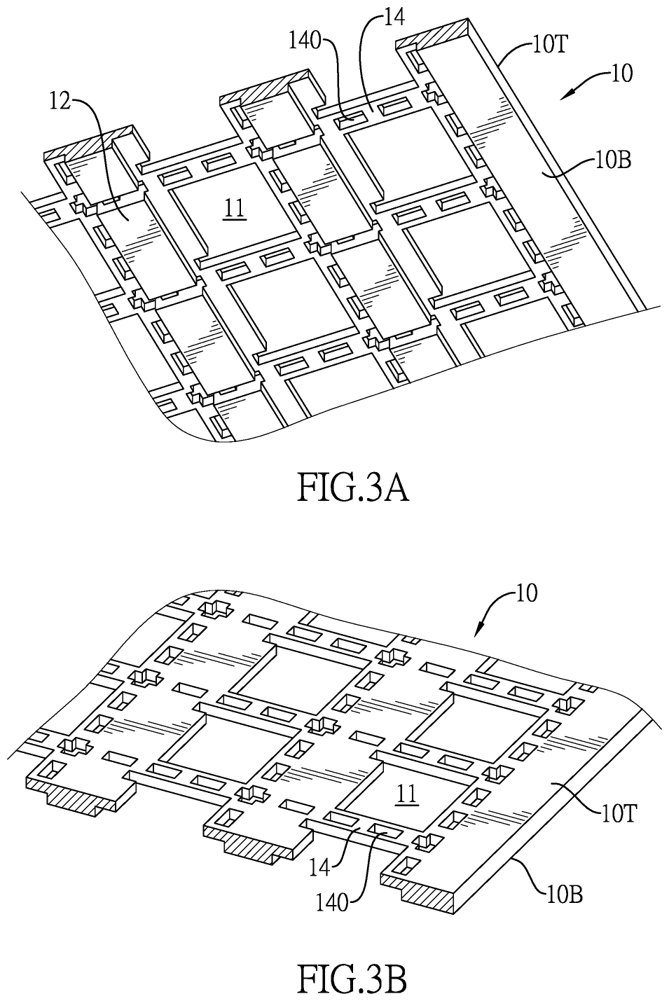

With reference to FIGS. 1, 2, 3A, and 3B, in an embodiment of the present invention, a vertical connection board (VCB) 10 is used in a manufacturing method of a semiconductor package as a conducting unit for electrically connecting to a die. The VCB 10 is a metal board (such as a copper board) with a first surface 10T and a second surface 10B. For ease of understanding, the first surface 10T is viewed as a top surface, and the second surface 10B is viewed as a bottom surface. With reference to FIG. 1, the VCB 10 is diced into multiple units 10U. The diced units 10U are lined up.

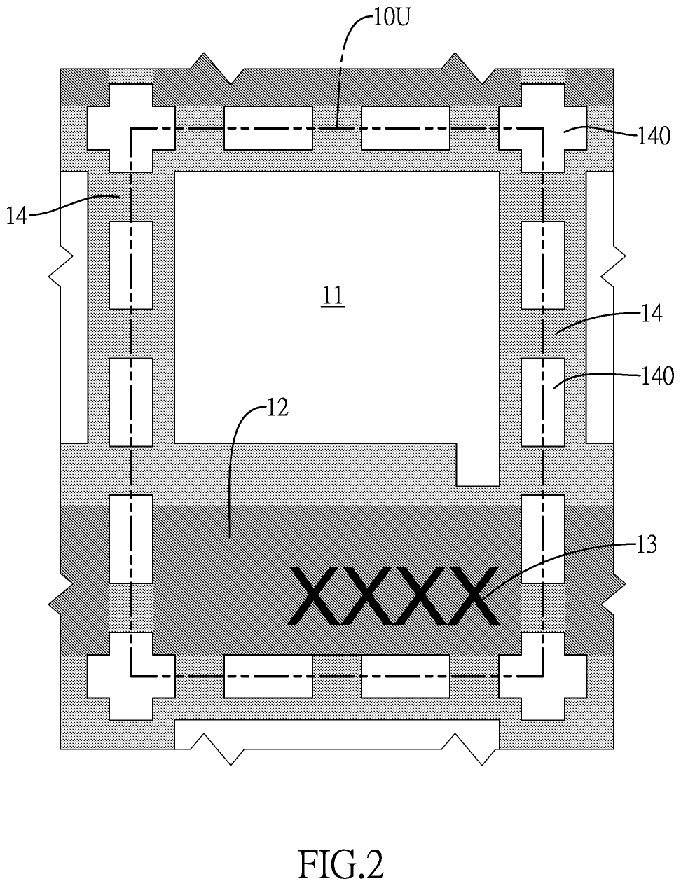

With reference to FIG. 2, an opening 11 is formed within each of the units 10U. The opening 11 connects the first surface 10T and the second surface 10B of the VCB 10, and the opening 11 is formed by fully etching the VCB 10. In an embodiment, a label section 12 is included on the VCB 10 on a side of the opening 11. A thickness of the label section 12 is unaffected by etching (as indicated by a darker grey area in FIG. 2). A label 13 is formed on a surface of the label section 12. The units 10U are differentiated and identified respectively by their unique labels 13. In other words, the label 13 may function as an identifier. For instance, when defects are detected in the units 10U, the label 13 serves as a reference for investigating manufacturing variables previously configured, or for identifying manufactured products in question of having the same serialized batch. In the present embodiment, the label 13 is formed on the second surface 10B.

A dicing lane 14 is formed in an adjacent area between the adjacent units 10U on the VCB 10. The dicing lane 14 is formed by making the VCB 10 thinner, and thus a thickness of the dicing lane (as indicated as a light grey area in FIG. 2) is less than the thickness of the label section 12. In the present embodiment, the second surface 10B of the VCB 10 is partially etched (such as using half etching) for making the VCB 10 thinner. Furthermore, multiple holes 140 are formed penetrating the VCB 10 along the dicing lane 14, allowing a dicing blade to more easily dice along the dicing lane 14.

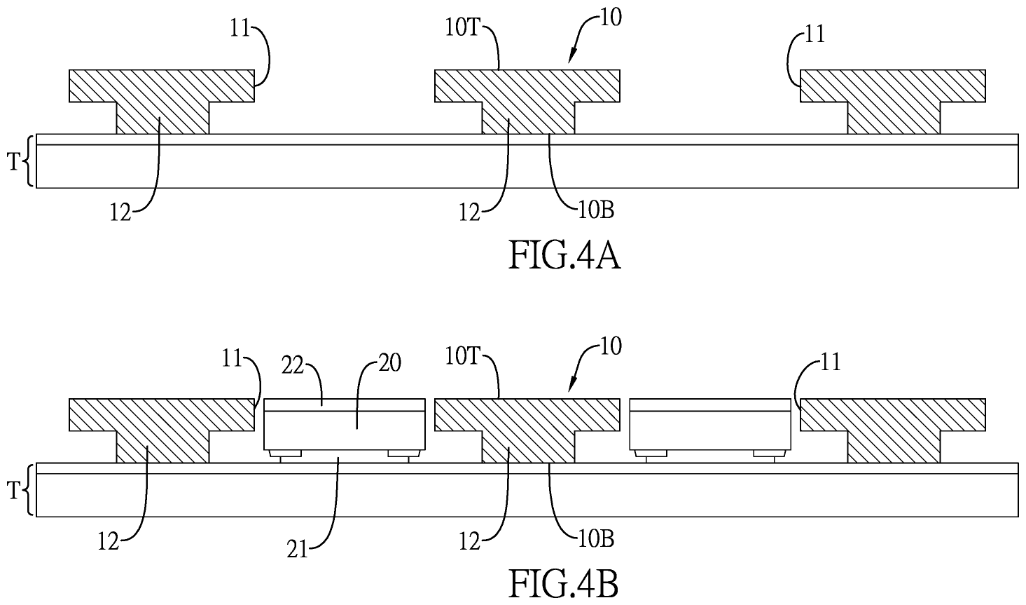

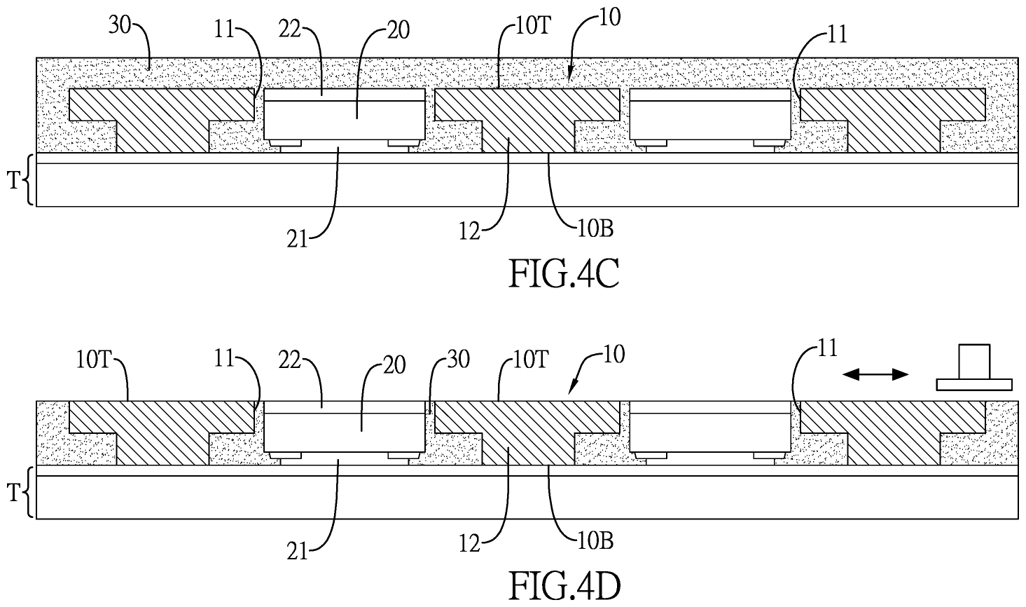

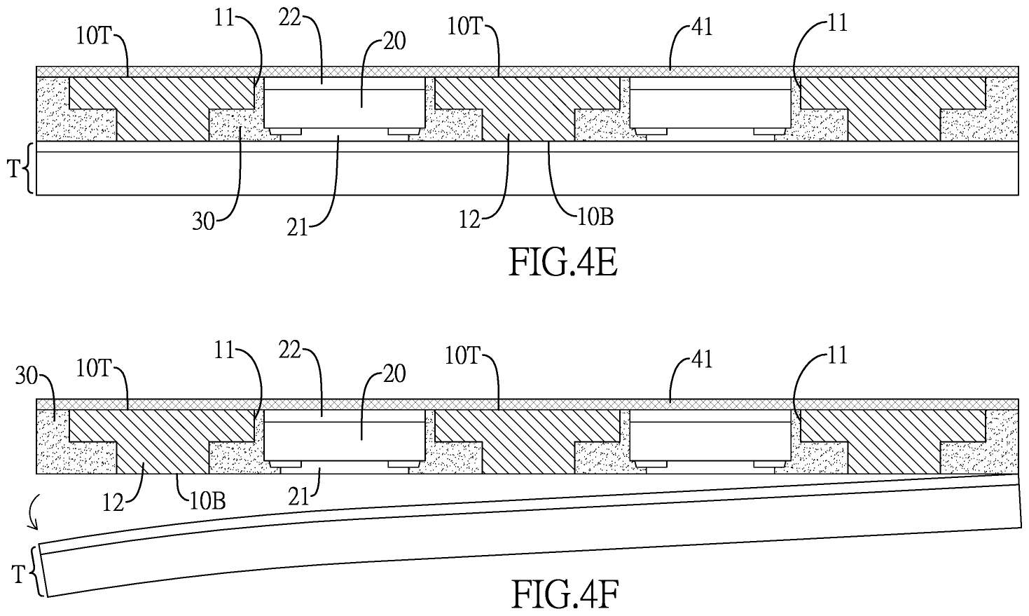

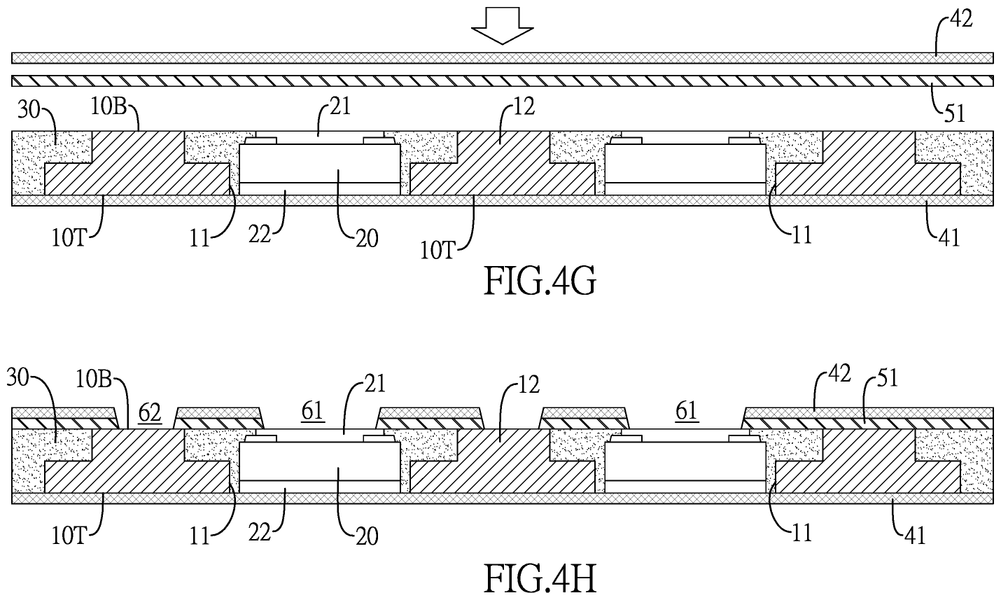

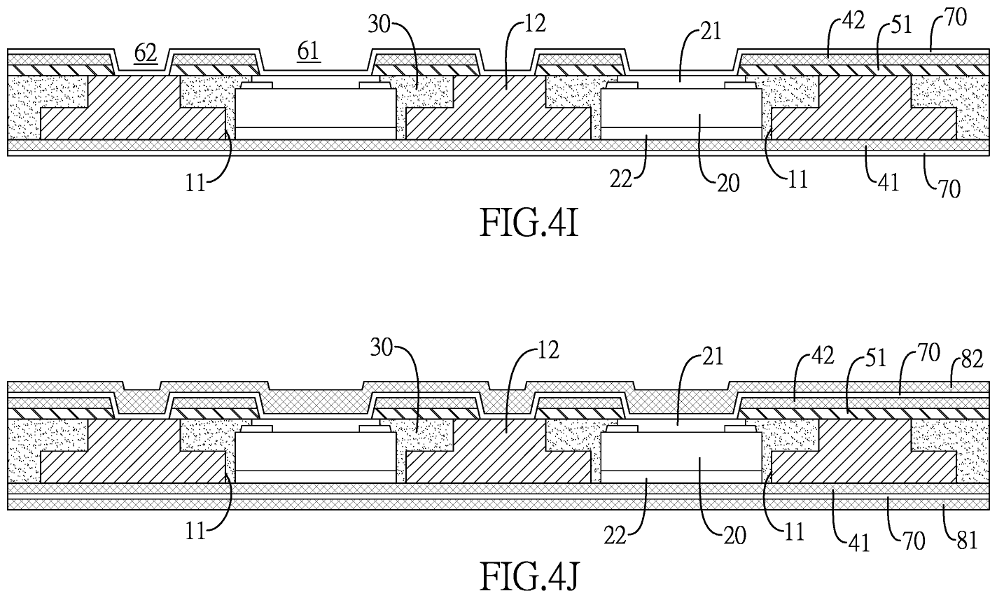

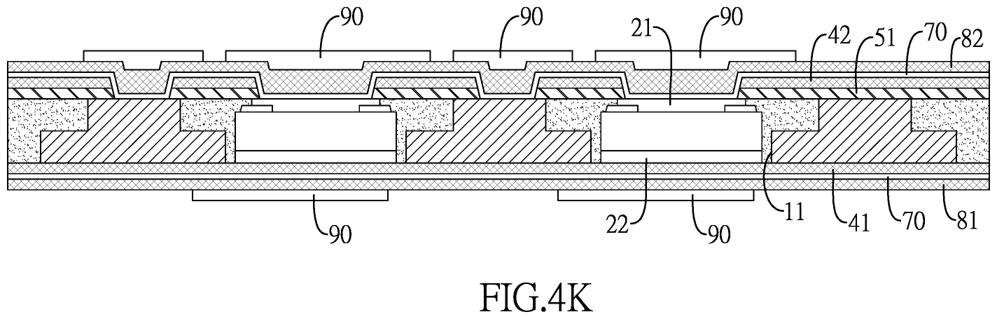

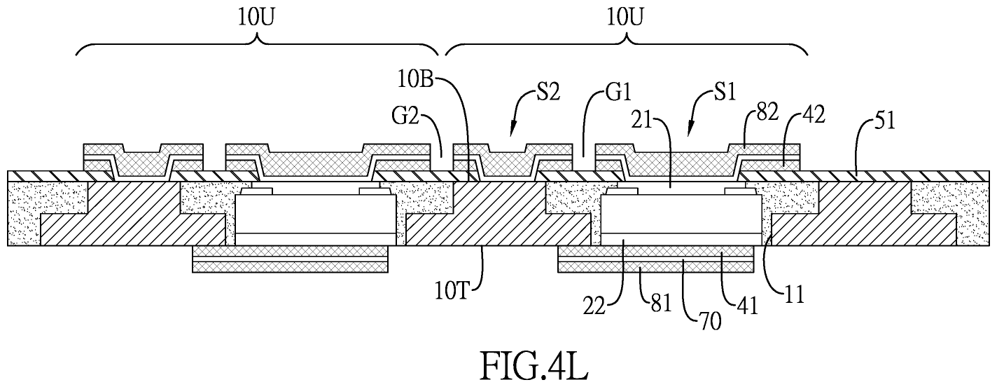

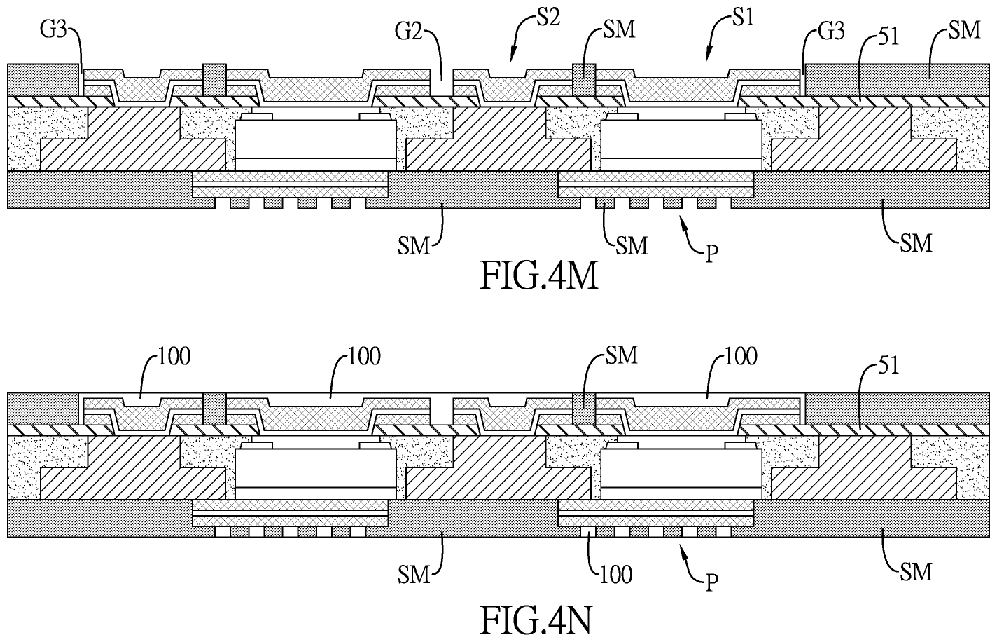

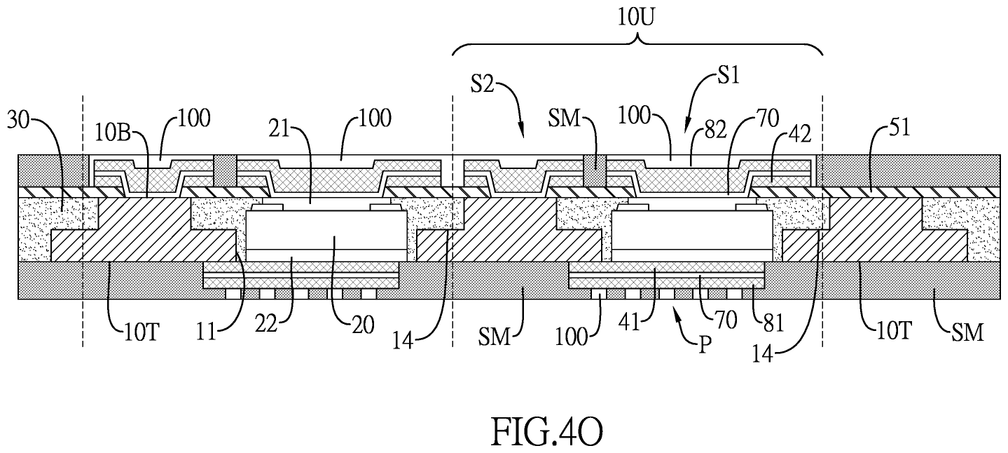

FIGS. 4A to 4O are perspective views of flow charts of the manufacturing method of the semiconductor package in the first embodiment of the present invention. FIGS. 4A to 4O are adapted to view from line 4-4 indicated in FIG. 1. FIG. 1 on the other hand shows the second surface 10B of the VCB 10.

With reference to FIGS. 4A and 4B, the second surface 10B of the VCB 10 is adhered to a surface of a film T. The film T includes an adhesion layer, and a plurality of the dies (such as semiconductor dies or chips) 20 are respectively mounted in the openings 11 of the VCB 10. In the present invention, an overall height of the die 20 is approximately the same as a thickness of the VCB 10. Contacts for conducting electric signals or electricity are mounted on a front surface and a back surface of each of the dies 20. For example, a first contact 21 is mounted on the front surface of the die 20, and a second contact 22 is mounted on the back surface of the die 20. In this embodiment, the font surface of the die with the first contact 21 is mounted on the film T. However, in another embodiment, the back surface of the die 20 with the second contact 22 is mounted on the film T instead. After the die 20 is mounted in the opening 11, the four sides of the die 20 still maintain a distance away from a side surface of the opening 11 by having a gap.

With reference to FIG. 4C, dielectric material (such as epoxy molding compound (EMC) is provided to a surface of the VCB 10 for forming a molding layer 30. The molding layer 30 covers around the four sides of the die 20 and the VCB 10.

With reference to FIG. 4D, a thickness of the molding layer 30 is made thinner by grinding a surface of the molding layer 30. This allows the second contact 22 on the back surface of the die 20 and the first surface 10T of the VCB 10 to be exposed from the molding layer 30.

With reference to FIG. 4E, a first conduction layer 41 is formed on the surface of the molding layer 30 with the exposed back surface of the die 20. This allows the second contact 22 on the back surface of the die 20 to be electrically connected to the first surface 10T of the VCB 10 via the first conduction layer 41. The first conduction layer 41 is formed by, for example, sputtering titanium copper on the surface of the molding layer 30.

With reference to FIG. 4F, after the first conduction layer 41 is formed, the film T is removed as shown in FIG. 4F.

With reference to FIG. 4G, after the film T is removed, the present invention proceeds to continue manufacturing steps for the front surface of the die 20. A first dielectric layer 51 and a second conduction layer 42 are respectively laminated to the second surface 10B of the VCB 10 and the front surface of the die 20. The first dielectric layer 51 has insulation properties, and the second conduction layer 42 is, for example, a copper film layer.

With reference to FIG. 4H, after the second conduction layer 42 is laminated, multiple pin holes 61 and 62 are formed by laser drilling the first dielectric layer and the second conduction layer 42. The pin holes 61 and 62 are formed at designated places for connection points of the semiconductor package. For example, a part of the pin hole 61 corresponds to the first contact 21 exposed from the front surface of the die 20, and another part of the pin hole 62 corresponds to the second surface 10B exposed from the VCB 10.

With reference to FIG. 4I, after the pin holes 61 and 62 are formed, a seed layer 70 is formed respectively for the first conduction layer 41 and an inner wall of each of the pin holes 61 and 62, and another seed layer 70 is formed on a surface of the second conduction layer 42. The seed layer 70 shown on an upper part of FIG. 4I covers the first contact 21 exposed from the pin holes 61 and the second surface 10B of the VCB 10 exposed from the pin holes 62. The seed layers 70 are deposited for electroplating in later parts of the manufacturing process. The seed layers 70 are deposited using conventional methods such as electroless plating, or sputtering, etc, and the seed layers 70 consist of metallic materials such as copper or titanium.

With reference to FIG. 4J, a first circuit layer 81 and a second circuit layer 82 are formed by respectively electroplating surfaces of the seed layers 70. The first circuit layer 81 and the second circuit layer 82 are respectively a cooper layer with a thickness greater than a thickness of the first conduction layer 41 and a thickness of the second conduction layer 42. The second circuit layer 82 formed on the front surface of the die 20 fills each of the pin holes 61 and 62.

With reference to FIG. 4K, a patterned mask 90 is respectively formed on a surface of the first circuit layer 81 and a surface of the second circuit layer 82. In an embodiment, the patterned masks 90 are respectively formed by mounting a dry film photoresist respectively on the surface of the first circuit layer 81 and the surface of the second circuit layer 82, and patterning the dry film photoresists. The patterned masks 90 cover designated places for having contacts of the semiconductor package.

With reference to FIG. 4L, places without being covered by the patterned masks 90 are etched away. As a result, redundant parts of the first circuit layer 81, the second circuit layer 82, the first conduction layer 41, the second conduction layer 42, and the seed layers 70 are etched away, until the first dielectric layer 51 of the second surface 10B of the VCB 10 and the first surface 10T of the VCB 10 are exposed. The second circuit layer 82, the seed layer 70, and the second conduction layer 42 remaining on the front surface of the die 20 are viewed as a first redistribution layer (RDL) that constitutes contacts of the semiconductor package. In the present embodiment, each of the units 10U includes a first pin S1 and a second pin S2. The first pin S1 is electrically connected to the first contact 21, and the second pin S2 is electrically connected to the second surface 10B of the VCB 10. A gap G1 is formed between the first pin S1 and the second pin S2 for preventing an electrical short between the first pin S1 and the second pin S2. Another gap G2 is formed between the adjacent units 10U. The gap G2 corresponds to a position of the dicing lane 14. The first circuit layer 81, the seed layer 70, and the first conduction layer 41 remaining on the back surface of the die 20 are viewed as a second redistribution layer. The second redistribution layer is used for electrically connecting the second contact 22 on the back surface of the die 20 to the VCB 10.

With reference to FIG. 4M, a solder mask SM is formed on the first dielectric layer 51 of the second surface 10B of the VCB 10. The solder mask SM is formed filling in the gap G1 between the first pin S1 and the second pin S2. However the solder mask SM is formed without filling in the gap G2 between the adjacent units 10U. An electroplating gap G3 is formed between the solder mask SM most peripheral to the VCB 10 and a side surface of the first pin S1 or a side surface of the second pin S2. Furthermore, the solder mask SM covers the first surface 10T and the molding layer 30 entirely on the first surface 10T of the VCB 10. In another embodiment, before forming the solder mask SM on the first surface 10T of the VCB 10, the solder mask SM is patterned for defining a patterned area P. The patterned area P is used to show words or marks indicating a product serial or a manufacturer name.

With reference to FIG. 4N, a surface protection layer 100 is formed on a surface of the first pin S1 and a surface of the second pin S2. In the present embodiment, the surface protection layer 100 is a metal layer formed by electroless plating or sputtering. Since the electroplating gap G3 and the gap G2 between the adjacent units 10U are formed, the surface protection layer 100 is formed filling in the electroplating gap G3 and the gap G2. Furthermore, on the other side of the VCB 10, the surface protection layer 100 is formed filling in the patterned area P for forming the words or marks.

With reference to FIG. 4O, after forming the surface protection layer 100, the present invention proceeds to a manufacturing step of singulation. This means that the VCB10 is diced along the dicing lanes 14 surrounding each of the units 10U (as indicated by the dash lines). The positions of the dicing lanes 14 are the positions of the VCB 10 partially etched to be thinner. When the VCB 10 is diced, a position of a blade or a laser is controlled for keeping the surface protection layer 100 on the side surface of the first pin S1 and the side surface of the second pin S2 located the most peripheral to the VCB 10.

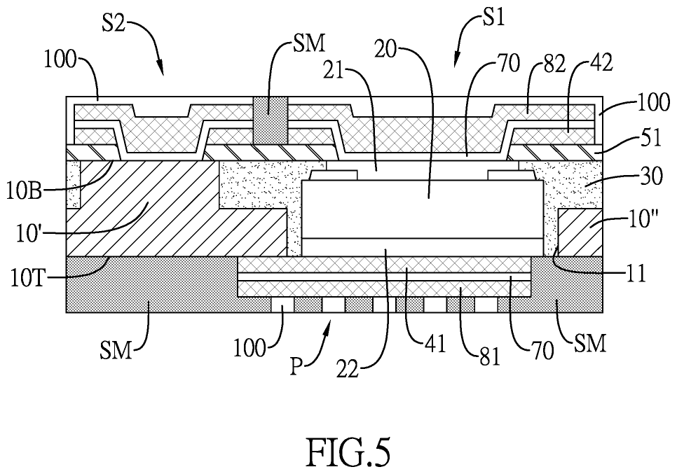

With reference to FIG. 5, once completing the manufacturing steps described in the flow charts from FIG. 4A to FIG. 4O, the semiconductor package shown in FIG. 5 is manufactured. A conductive block 10′ is formed by dicing the VCB 10. The conductive block 10′ is electrically connected to the second pin S2 and the second contact 22 of the die 20. In the present embodiment, the overall height of the die 20, the thickness of the molding layer 30, and a thickness of the conductive block 10′ are roughly identical.

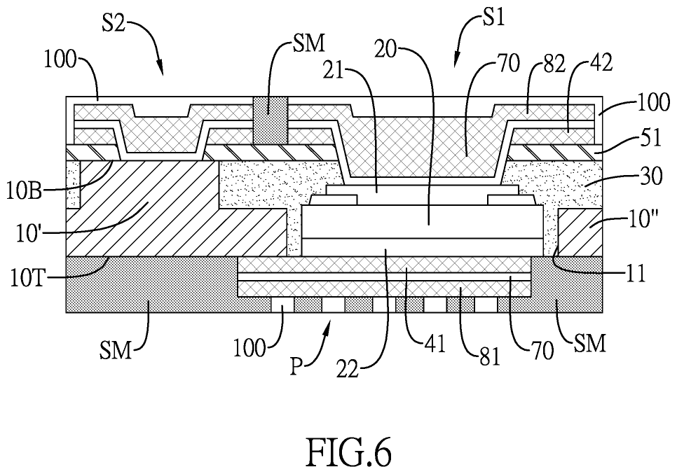

With reference to FIG. 6, in another embodiment, the thickness of the molding layer 30 and the thickness of the conductive block 10′ are roughly identical. However the overall height of the die 20 is less than the said thickness of the molding layer 30.

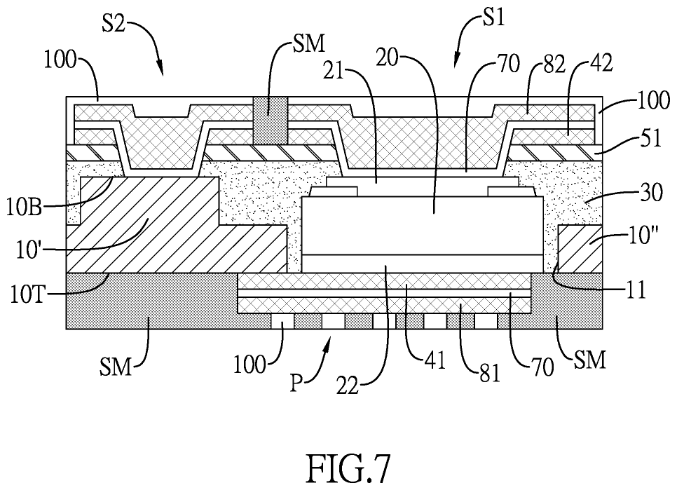

With reference to FIG. 7, in yet another embodiment, the overall height of the die 20 and the thickness of the conductive block 10′ are roughly identical. However the thickness of the molding layer 30 is greater than the overall height of the die 20.

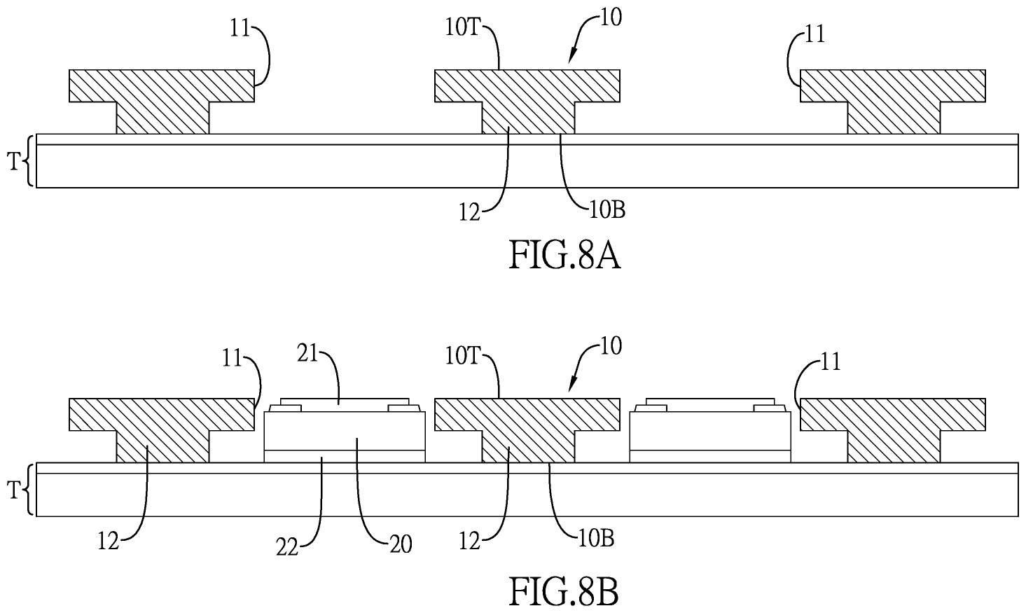

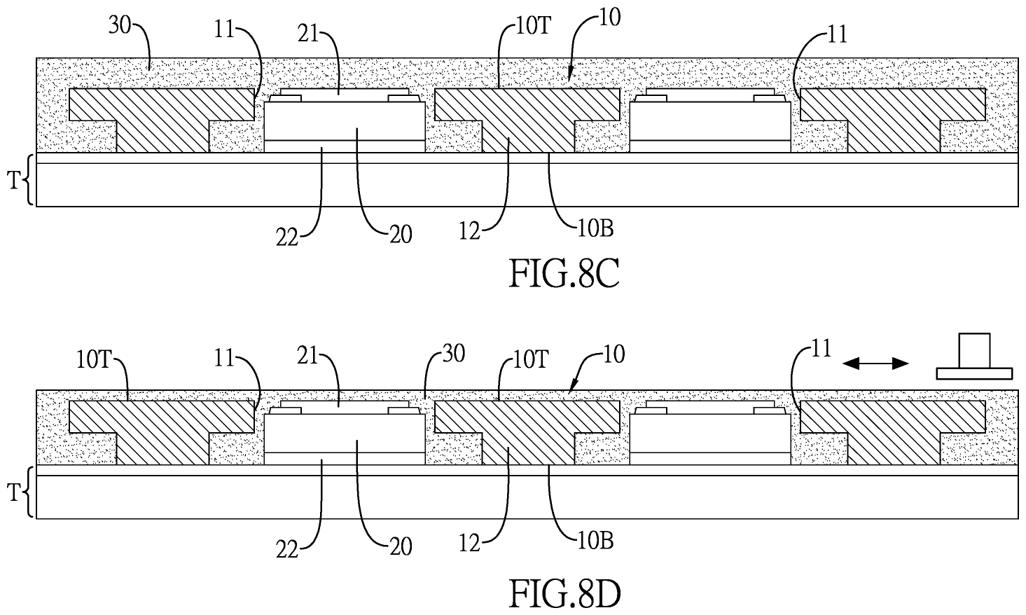

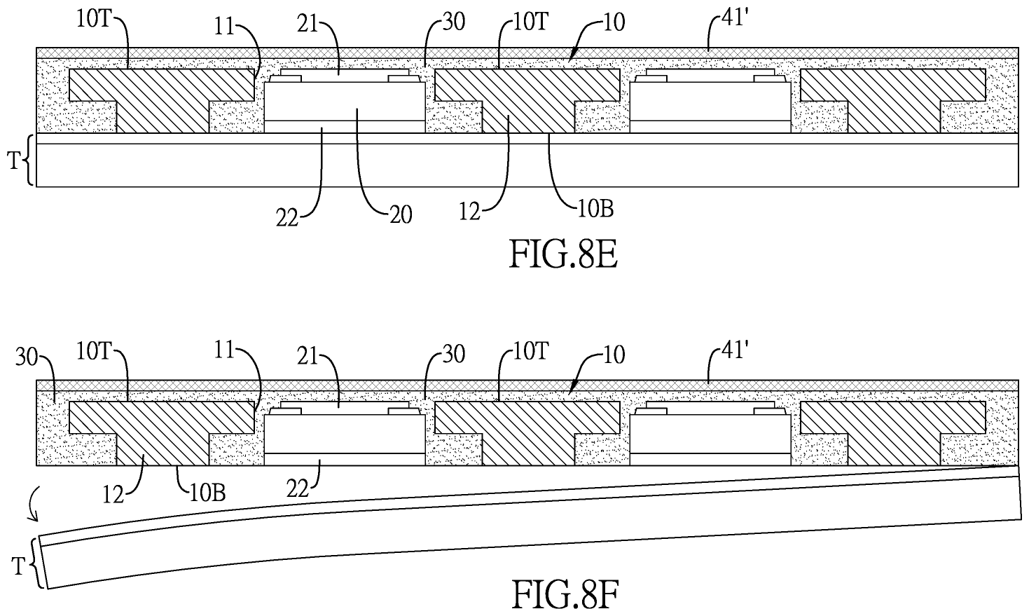

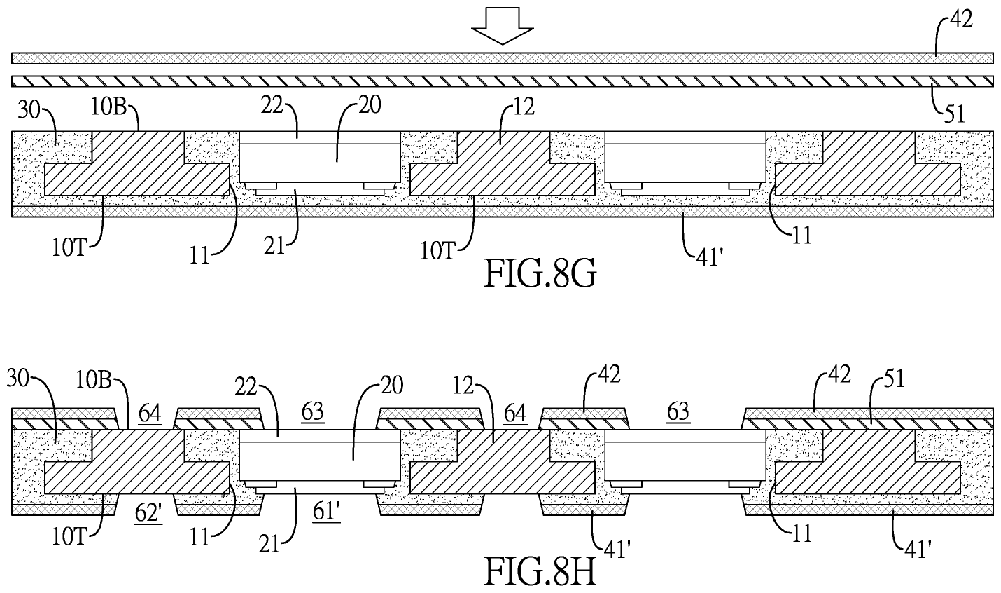

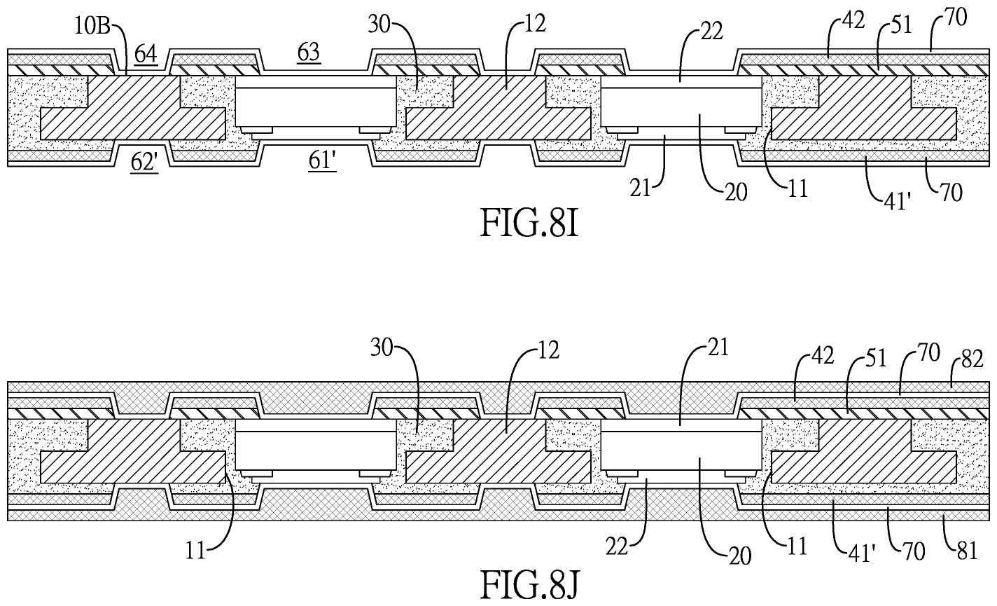

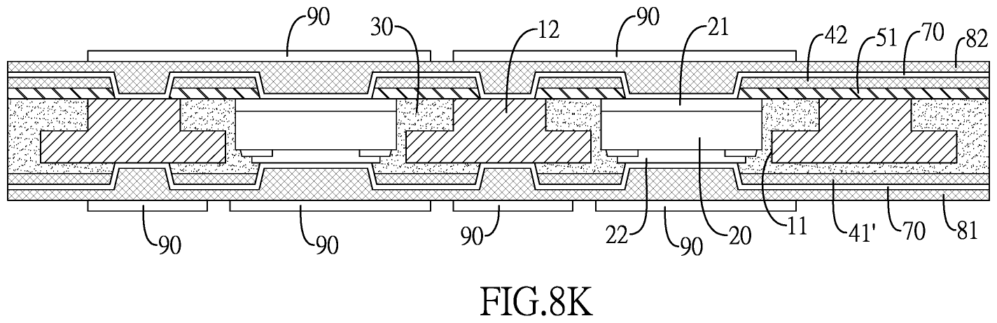

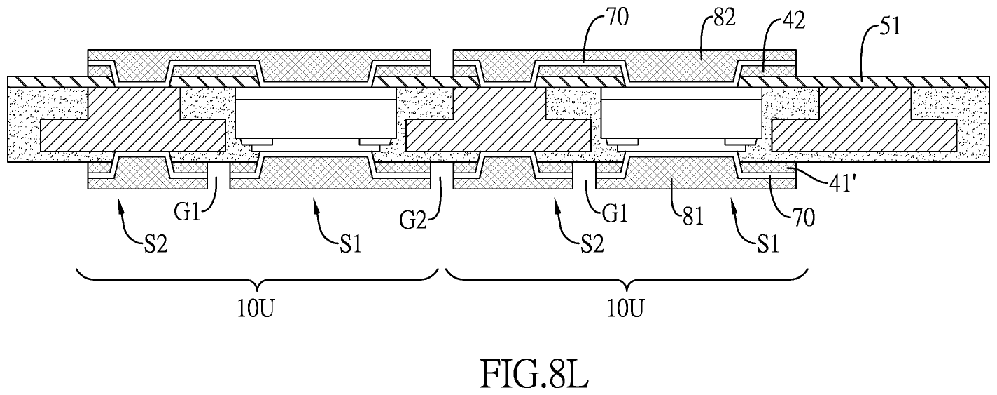

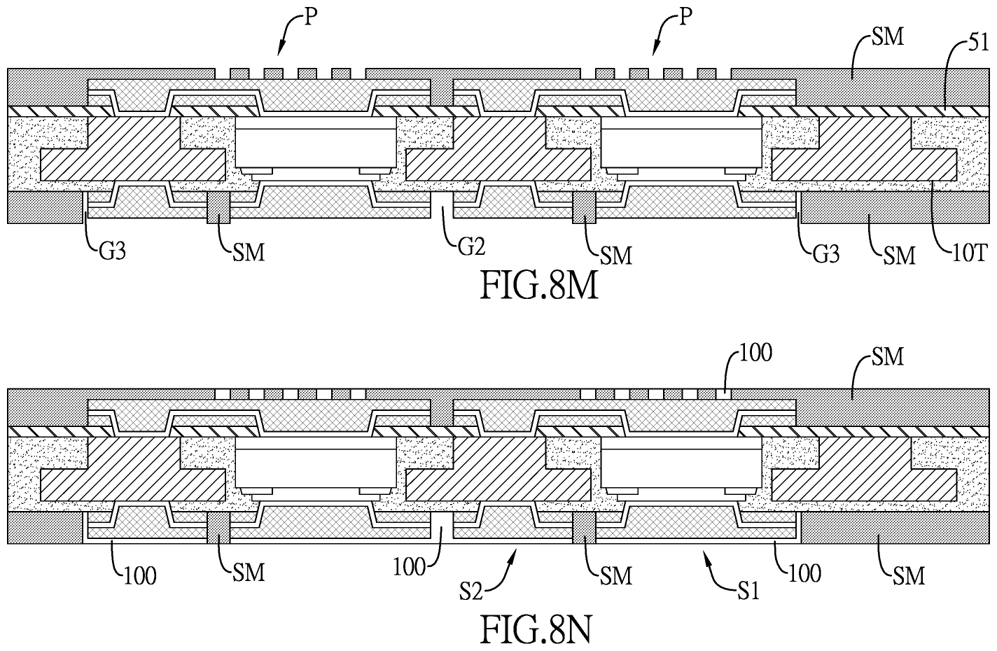

With reference to FIGS. 8A to 8O, FIGS. 8A to 8O are perspective views of flow charts of the manufacturing method of the semiconductor package in the second embodiment of the present invention. More particularly, the manufacturing steps described in FIGS. 8A to 8D are roughly identical to the manufacturing steps described in FIGS. 4A to 4D, the difference being that the film T is adhered to the back surface of the die 20 with the second contact 22.

With reference to FIG. 8D, in a grinding step, the molding layer 30 partly remains on the front surface of the die 20 and the first surface 10T of the VCB 10. As such, the thickness of the molding layer 30 is greater than the overall height of the die 20 and the thickness of the VCB 10.

With reference to FIG. 8E, a first conduction layer 41′ is formed on the molding layer 30. The first conduction layer 41′ is formed by, for example, sputtering titanium copper on the surface of the molding layer 30.

With reference to FIG. 8F, after the first conduction layer 41′ is formed, the film T is removed.

With reference to FIG. 8G, after the film T is removed, the present invention proceeds to continue the manufacturing step for the back surface of the die 20 and the second surface 10B of the VCB 10. A first dielectric layer 51 and a second conduction layer 42 are laminated to the second surface 10B of the VCB 10. The first dielectric layer 51 has insulation properties, and the second conduction layer is, for example, a copper film layer.

With reference to FIG. 8H, after the second conduction layer 42 is laminated, layers formed on the first surface 10T and the second surface 10B of the VCB 10 are drilled. More particularly, multiple contact openings 63 and 64 are formed by laser drilling the first dielectric layer 51 and the second conduction layer 42 layered on the second surface 10B of the VCB 10. Parts of the contact openings 63 expose the second contact 22 on the back surface of the die 20, and other parts of the contact openings 64 expose the second surface 10B of the VCB 10. Furthermore, multiple pin holes 61′ and 62′ are formed by laser drilling the first conduction layer 41′ and the molding layer 30 located on a side of the first surface 10T of the VCB 10. The pin holes 61′ and 62′ are formed at designated places for connection points of the semiconductor package. For example, a part of the pin hole 61′ corresponds to the first contact 21 exposed from the front surface of the die 20, and another part of the pin hole 62′ corresponds to the first surface 10T exposed from the VCB 10.

With reference to FIG. 8I, after the pin holes 61′, 62′ and the contact openings 63, 64 are formed, a seed layer 70 is formed respectively for the first conduction layer 41′ and an inner wall of each of the pin holes 61′ and 62′, and another seed layer 70 is formed respectively for the second conduction layer 42 and an inner wall of each of the contact openings 63, 64. The seed layer 70 shown on an upper part of FIG. 8I covers the second contact 22 of the die 20 and the second surface 10B of the VCB 10. The seed layer 70 shown on a bottom part of FIG. 8I covers the first contact 21 on the front surface of the die 20 and the first surface 10T of the VCB 10. T

With reference to FIG. 8J, a first circuit layer 81 and a second circuit layer 82 are formed by respectively electroplating the surfaces of the seed layers 70. The first circuit layer 81 and the second circuit layer 82 are respectively a cooper layer with a thickness greater than a thickness of the first conduction layer 41′ and the thickness of the second conduction layer 42. The first circuit layer 81 fills each of the pin holes 61′ and 62′, and the second circuit layer 82 fills each of the contact openings 63, 64.

With reference to FIG. 8K, a patterned mask 90 is respectively formed on the surface of the first circuit layer 81 and the surface of the second circuit layer 82 through electroplating. In an embodiment, the patterned masks 90 are respectively formed by mounting a dry film photoresist respectively on the surface of the first circuit layer 81 and the surface of the second circuit layer 82, and patterning the dry film photoresists. The patterned masks 90 respectively cover the surface of the first circuit layer 81 and the surface of the second circuit layer 82, and thus the patterned masks 90 respectively cover designated places for having pins of the semiconductor package and cover designated places for having circuits electrically connecting the second contact 22 and the VCB 10.

With reference to FIG. 8L, places without being covered by the patterned masks 90 are etched away. As a result, redundant parts of the first circuit layer 81 and the first conduction layer 41′ are etched away for exposing the surface of the molding layer 30. Furthermore, redundant parts of the second circuit layer 82, the second conduction layer 42, and the seed layers 70 are etched away, until the first dielectric layer 51 of the second surface 10B of the VCB 10 is exposed. The first circuit layer 81, the seed layer 70, and the first conduction layer 41′ remaining on the front surface of the die 20 are viewed as a first redistribution layer (RDL) that constitutes contacts of the semiconductor package. In the present embodiment, each of the units 10U includes a first pin S1 and a second pin S2. The first pin S1 is electrically connected to the first contact 21, and the second pin S2 is electrically connected to the VCB 10. A gap G1 is formed between the first pin S1 and the second pin S2 for preventing an electrical short between the first pin S1 and the second pin S2. Another gap G2 is formed between the adjacent units 10U. The second circuit layer 82, the seed layer 70, and the second conduction layer 42 remaining on the back surface of the die 20 are viewed as a second redistribution layer. The second redistribution layer is used for electrically connecting the second contact 22 on the back surface of the die 20 to the second surface 10B of the VCB 10.

With reference to FIG. 8M, a solder mask SM is formed on the molding layer on the first surface 10T of the VCB 10. The solder mask SM is formed filling the gap G1 between the first pin S1 and the second pin S2. However the solder mask SM is formed without filling the gap G2 between the adjacent units 10U. Furthermore, an electroplating gap G3 is formed between the solder mask SM most peripheral to the VCB 10 and a side surface of the first pin S1 or a side surface of the second pin S2. Furthermore, the solder mask SM covers the second surface 10B and the first dielectric layer 51 entirely. In another embodiment, before forming the solder mask SM, the solder mask SM in each of the units 10U is patterned for respectively defining a patterned area P. The patterned area P is used to show words or marks indicating a product serial or a manufacturer name.

With reference to FIG. 8N, a surface protection layer 100 is formed on the surface of the first pin S1 and the surface of the second pin S2. In the present embodiment, the surface protection layer 100 is a metal layer formed by electroless plating or sputtering. Since the electroplating gap G3 and the gap G2 between the adjacent units 10U are formed, the surface protection layer 100 is formed filling in the electroplating gap G3 and the gap G2. Furthermore, on the other side of the VCB 10, the surface protection layer 100 is formed filling the patterned area P for forming the words or marks defaulted by the metal layer.

With reference to FIG. 8O, after forming the surface protection layer 100, the present invention proceeds a manufacturing step of singulation. This means that the VCB10 is diced along the dicing lanes 14 surrounding each of the units 10U (as indicated by the dash lines). The positions of the dicing lanes 14 are the positions of the VCB 10 partially etched to be thinner. When the VCB 10 is diced, a position of a blade or a laser is controlled for keeping the surface protection layer 100 on the side surface of the first pin S1 and the side surface of the second pin S2.

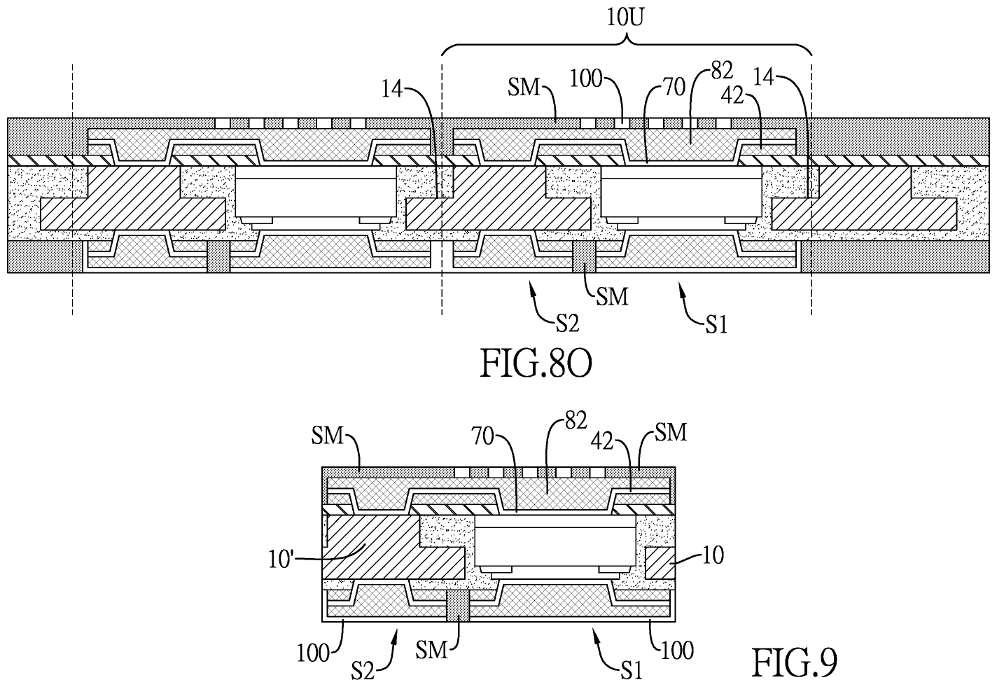

With reference to FIG. 9, once the manufacturing steps described in the flow charts from FIG. 8A to FIG. 8O, the semiconductor package shown in FIG. 9 is manufactured. A conductive block 10′ is formed by dicing the VCB 10. The conductive block 10′ is electrically connected to the second pin S2 and the second contact 22 of the die 20. A structure of the semiconductor package shown in FIG. 9 is nearly identical to the structure of the semiconductor package in the embodiment shown in FIG. 5. However, the conductive block 10′ in FIG. 9 and the conductive block 10′ in FIG. 5 face different directions. The conductive block 10′ in FIG. 9 is electrically connected to the second pin S2 from the first surface 10T, yet the conductive block 10′ in FIG. 5 is electrically connected to the second pin S2 from the second surface 10B.

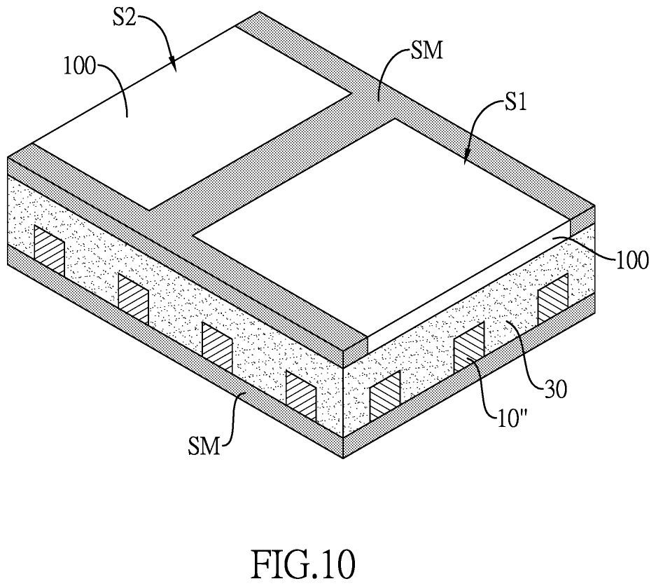

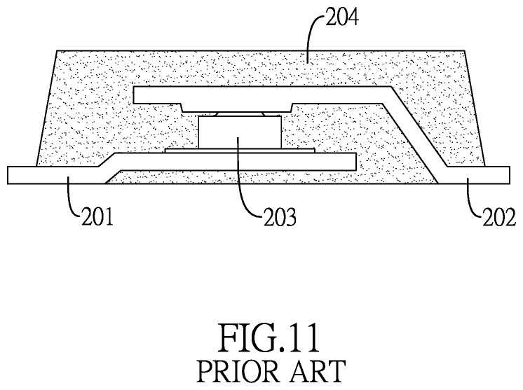

With reference to FIG. 10, an external view of the semiconductor package manufactured by the aforementioned steps resembles a package body in a flat rectangular shape. This allows the semiconductor package to be a surface mounting package. The package body includes a top surface and a bottom surface on opposite sides, and includes four side surfaces. The bottom surface is the surface with the first pin S1 and the second pin S2 exposed.

With reference to FIGS. 5 to 7, or FIG. 9, the cross-sectional views show the semiconductor package having a conductive block 10′ and multiple metal blocks 10″. The conductive block 10′ and the metal blocks 10″ are formed by dicing the VCB 10. The conductive block 10′ has a T-shaped cross-section. Surfaces on opposite sides of the conductive block 10′ are designated as a first contact surface and a second contact surface. The conductive block 10′ and the metal blocks 10″ surround the die 20, but each of the metal blocks 10″ stays electrically isolated from the die 20.

The first contact 21 on one surface of the die 20 is electrically connected to the first pin S1, and the second contact 22 on another surface of the die 20 is electrically connected to the first contact surface of the conductive block 10′ (such as the first surface 10T shown in FIG. 5) via the second redistribution layer. The second contact surface of the conductive block 10′ (such as the second surface 10B shown in FIG. 5) is electrically connected to the second pin S2. The first pin S1 and the second pin S2 are both exposed at the bottom surface of the package body, and the first pin S1 and the second pin S2 respectively extend to and cover two opposite sides of the package body.

The surface of the first pin S1 and the surface of the second pin S2 are respectively covered by the surface protection layer 100 made of metal. When the bottom surface of the package body is soldered onto a circuit board, the solder is able to move to surfaces of two opposite sides of the package body via the first pin S1 and the second pin S2 through capillary action. As such, a user of the present invention is able to easily examine soldering qualities of the package body. Furthermore, although multiple diced surfaces of the package body are exposed as the VCB 10 is diced, these diced surfaces are without being surface treated, and therefore an oxidization layer (such as a copper oxide layer) will respectively form on each of the diced surfaces. Each of the oxidization layers is able to prevent solder from attaching, and therefore each of the oxidization layers is able to prevent an electrical short between the first pin S1 and the second pin S2 during the soldering process.

In regards to the aforementioned semiconductor package, the die 20 is able to dissipate heat externally through heat conduction of the first pin S1, the second pin S2, and the conductive block 10′. As such, the present invention provides cooling properties for dissipating heat better than prior arts. Furthermore, since the semiconductor package has great electrical conductivity, the present invention also conducts greater electrical current than prior arts.

What is claimed is:

1. A heat dissipative semiconductor package, comprising:
a package body, in a flat rectangular shape, and having a top surface, a bottom surface, and four side surfaces;
a die, having two opposite sides; wherein the two opposite sides each respectively have a first contact and a second contact;
a conductive block, mounted a distance away from a side of the die by having a gap; wherein the conductive block has a first contact surface and a second contact surface;
multiple metal blocks, lined up around the die and without electrically connecting to the die; wherein a dicing surface of each of the metal blocks is exposed to one of the side surfaces of the package body;
a molding layer, covering the die, the conductive block, and the metal blocks, and exposing the four side surfaces of the package body;
a first redistribution layer, including a first pin and a second pin;
wherein the first pin is electrically connected to the first contact of the die, and the first pin is exposed from the bottom surface of the package body to curve, extend, and cover one of the side surfaces of the package body;
wherein the second pin is electrically connected to the second contact surface of the conductive block, and the second pin is exposed from the bottom surface of the package body to curve, extend, and cover another one of the side surfaces of the package body;
a second redistribution layer, electrically connected to the second contact of the die and the first contact surface of the conductive block; and
a solder mask, formed on the bottom surface and the top surface of the package body; wherein the solder mask on the bottom surface insulates the first pin and the second pin, and the solder mask on the bottom surface covers the second redistribution layer.

2. The heat dissipative semiconductor package as claimed in claim 1, wherein the first pin and the second pin comprise multiple layers of conductive material;
a surface protection layer made of metal respectively covers an external surface of the first pin and an external surface of the second pin.

3. The heat dissipative semiconductor package as claimed in claim 2, wherein the first redistribution layer and the second redistribution layer are layered with the same layers of conductive material.

4. The heat dissipative semiconductor package as claimed in claim 1, wherein a thickness of the conductive block between the first contact surface and the second contact surface is greater than a thickness of any one of the metal blocks.

5. The heat dissipative semiconductor package as claimed in claim 1, wherein the metal blocks exposed on the side surfaces of the package body are electrically isolated from the first pin and the second pin.

6. The heat dissipative semiconductor package as claimed in claim 2, wherein a patterned area is formed on the solder mask on the bottom surface, and the patterned area is filled with a same metal material of the surface protection layer.

7. The heat dissipative semiconductor package as claimed in claim 1, wherein a serial is formed on the first contact surface or the second contact surface of the conductive block.

8. The heat dissipative semiconductor package as claimed in claim 1, wherein the conductive block and the metal blocks are formed by dicing a same metal board; and the conductive block has a T-shaped cross-section.
